(19) United States
(12) Patent Application Publication
(10) Pub. No.: US 2026/0150498 A1
(43) Pub. Date: May 28, 2026

(54) BLIND SPOT DETECTION DEVICE

(71) Applicant: Hongyi Optical Co., Ltd., Taipei City (TW)

(72) Inventors: Yao-Tang Chang, New Taipei City (TW); Chia-Jung Lin, Taoyuan City (TW); Tzu Yu Lin, Taoyuan City (TW)

(73) Assignee: Hongyi Optical Co., Ltd., Taipei City (TW)

(21) Appl. No.: 19/026,402

(22) Filed: Jan. 17, 2025

(30) Foreign Application Priority Data
Nov. 27, 2024 (TW) 113145720

(51) Int. Cl. H10K 50/842; B60R 1/12; H10K 50/115; H10K 50/86

(52) U.S. Cl. CPC H10K 50/8426; B60R 1/12; H10K 50/865; B60R 2001/1223; H10K 50/115

(57) ABSTRACT

A blind spot detection device, including a rearview mirror, an electroluminescent quantum dot element, and a sealant layer. The rearview mirror has a groove and a light-transmitting area corresponding to the groove, and the electroluminescent quantum dot element is correspondingly disposed in the groove. The sealant layer is disposed between the electroluminescent quantum dot element and the rearview mirror.

### CROSS-REFERENCE TO RELATED APPLICATION

This application claims the priority benefit of Taiwan application serial no. 113145720, filed on Nov. 27, 2024. The entirety of the above-mentioned patent application is hereby incorporated by reference herein and made a part of this specification.

### BACKGROUND

### Technical Field

The disclosure relates to a detection device, and in particular to a blind spot detection device.

### Description of Related Art

When a vehicle is being driven, the rearview mirror is used to observe vehicles coming from behind to ensure driving safety. However, the range of vision that the rearview mirror may cover is limited, resulting in a blind spot that the driver cannot observe through the rearview mirror. This affects driving safety.

Therefore, the market has developed blind spot detection systems to solve the above problem. When a vehicle enters the blind spot of the rearview mirror, the radar sensor of the blind spot detection system may detect the vehicle in the blind spot. After sensing the distance and speed of the adjacent vehicle, a warning light installed on the rearview mirror flashes or lights up to alert the driver to pay attention to the vehicle behind and prevent collisions. However, existing warning lights have limited brightness, complex structures, insufficient light uniformity, and significant light loss. The above problems still need to be addressed by relevant manufacturers.

### SUMMARY

The disclosure provides a blind spot detection device, which has a good light source brightness, a good light conversion efficiency, a uniform light emission, and a simple structure. In addition, a light source has an extremely low thickness and does not require additional optical elements, which is beneficial for a miniaturization and a versatility of the blind spot detection device.

In an embodiment of the disclosure, the blind spot detection device includes a rearview mirror, an electroluminescent quantum dot element, and a sealant layer. The rearview mirror has a groove and a light-transmitting area corresponding to the groove, and the electroluminescent quantum dot element is correspondingly disposed in the groove. The sealant layer is disposed between the electroluminescent quantum dot element and the rearview mirror.

Based on the above, a warning light source of the blind spot detection device in the embodiment of the disclosure is the electroluminescent quantum dot element. Because the electroluminescent quantum dot element has an extremely low thickness and is a thin-film surface light source, the blind spot detection device has advantages such as a uniform light emission, being energy efficient, a high brightness, and a high light conversion efficiency. When applied to a blind spot detection, no secondary optical design (e.g., light homogenizing elements, optical path adjustment elements, or lampshades) is required to convert a point light source into a surface light source. While providing a wide-angle light emission to facilitate a driver's observation, the electroluminescent quantum dot element also reduces a volume of the device. Furthermore, because the thin-film electroluminescent quantum dot element has a characteristic of uniform and consistent thickness, no special structural treatment (e.g., redesigning an optical module, a dimension, or a housing) is required for different rearview mirrors. A unified size may be applied to all backlight sources for the blind spot detection. As a required pattern or a specific size may be displayed through the light-transmitting area of a nameplate, the blind spot detection device may be effectively standardized to significantly reduce costs. Additionally, the left and right rearview mirrors may also be easily shared, increasing the versatility of the blind spot detection device.

To make the features and advantages of the disclosure more comprehensible, several embodiments accompanied with drawings are described in detail as follows.

### BRIEF DESCRIPTION OF THE DRAWINGS

FIG. 1 is an external schematic diagram of a blind spot detection device in an embodiment of the disclosure.

FIG. 2A is a structural schematic diagram of the blind spot detection device in an embodiment of the disclosure.

FIG. 2B is a schematic diagram of the light emission viewing angle of the blind spot detection device in FIG. 2A.

FIGS. 3A and 3B are structural schematic diagrams of the electroluminescent quantum dot element in an embodiment of the blind spot detection device of the disclosure.

FIG. 4A is a schematic diagram of the light emission effect of a substrate with a graded refractive index in an embodiment of the disclosure.

FIG. 4B is a schematic diagram of the light emission effect of a substrate with a fixed refractive index in a comparative example.

FIG. 5 is a circuit diagram of the blind spot detection device in an embodiment of the disclosure.

FIG. 6 is a schematic comparison diagram of the blind spot detection device in an embodiment of the disclosure with other light sources.

FIGS. 7A to 7C are cross-sectional schematic diagrams of the blind spot detection device in an embodiment of the disclosure. FIG. 7D is a schematic diagram of the warning light pattern presented by the blind spot detection device in an embodiment of the disclosure.

### DESCRIPTION OF THE EMBODIMENTS

As used herein, “about”, “approximately”, or “substantially” includes the stated value and the average value within the acceptable deviation range of the specific value determined by a person of ordinary skill in the art, taking into account the measurement in question and a certain amount of measurement-related error (i.e., the limitation of the measurement system). For example, “about” may mean within one or more standard deviations of the stated value, or within +30%, +20%, +10%, +5%. Furthermore, “about”, “approximate” or “substantially” used herein may be according to measuring properties, cutting properties or other properties to select a more acceptable range of deviation or standard deviation, and not one standard deviation may be applied to all properties.

In the drawings, for clarity, the thicknesses of layers, films, panels, and regions are enlarged. It should be understood that when elements such as layers, films, regions, or substrates are described as being “on” another element or “connected to” another element, they may be directly on or connected to the other element, or there may also be intermediate elements. In contrast, when an element is described as being “directly on” another element or “directly connected to” another element, no intermediate element is present. As used herein, “connected” may refer to physical and/or electrical connections. Furthermore, “electrically connected” may include the presence of other elements between two elements.

Reference will now be made in detail to exemplary embodiments of the disclosure, examples of which are illustrated in the accompanying drawings. Wherever possible, the same reference numerals are used in the drawings and description to represent the same or similar parts.

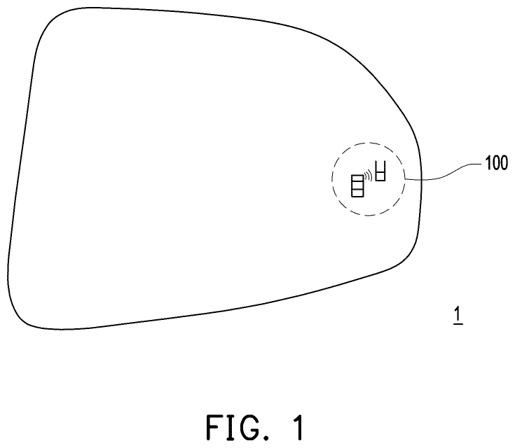

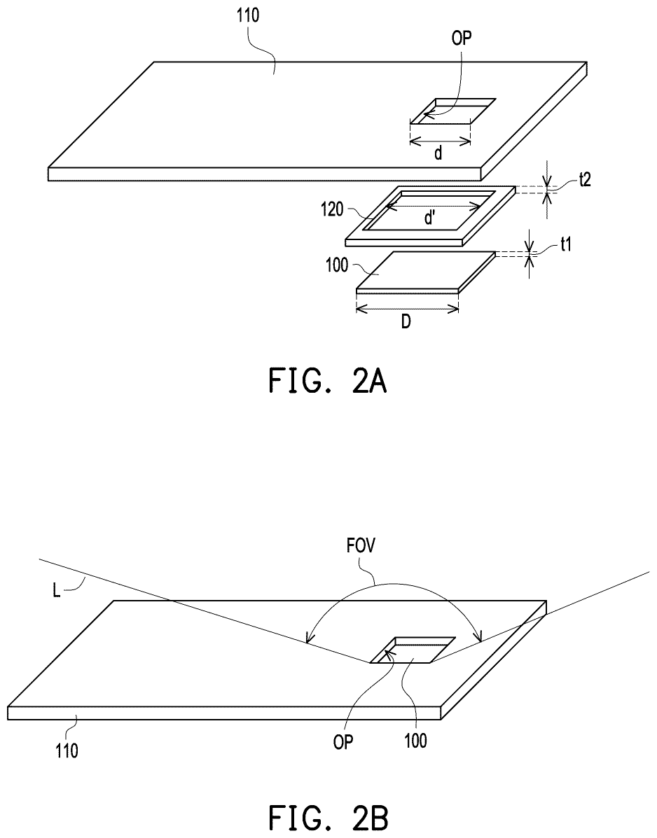

FIG. 1 is an external schematic diagram of a blind spot detection device in an embodiment of the disclosure. FIG. 2A is a structural schematic diagram of the blind spot detection device in an embodiment of the disclosure. FIG. 2B is a schematic diagram of light emission of the blind spot detection device in FIG. 2A. Referring to FIGS. 1 to 2B at the same time, the blind spot detection device 1 includes a rearview mirror 110 (indicated in FIG. 2A), an electroluminescent quantum dot element 100, and a sealant layer 120. The sealant layer 120 is disposed between the electroluminescent quantum dot element 100 and the rearview mirror 110. The blind spot detection device 1 includes a radar sensor (not shown) to detect vehicles located in the blind spot. If the vehicle's distance or speed is considered to pose a danger to the driver when changing lanes, the radar sensor may transmit an electrical signal to the electroluminescent quantum dot element 100 on the rearview mirror 110. The electroluminescent quantum dot element 100 displays a warning light (as shown in FIG. 1 with two vehicle patterns and a Wi-Fi signal pattern) to alert the driver. It should be noted that the blind spot detection device 1 may further include a circuit board (not shown) as a transmission circuit, enabling the blind spot detection device 1 to provide the electrical signals or electrical power required by the radar sensor and the electroluminescent quantum dot element 100. In addition, the rearview mirror 110 has a groove OP and a light-transmitting area corresponding to the groove OP. The groove OP is a region with reduced thickness formed on the rearview mirror 110 through an etching process, thinning process, or engraving process. When the electroluminescent quantum dot element 100 is not lit, the groove OP may still provide a reflective light beam function to allow the driver to observe vehicles coming from behind. When the electroluminescent quantum dot element 100 is lit, the groove OP, due to its reduced thickness, has a lower visible light reflectance and a higher visible light transmittance. The light-transmitting area may be formed with a warning light-transmitting pattern (such as the two vehicle patterns and Wi-Fi signal pattern mentioned above). The rearview mirror 110 may be applied to the left-side rearview mirror or the right-side rearview mirror of a vehicle. The disclosure is not limited thereto.

The electroluminescent quantum dot element 100 is correspondingly disposed at the groove OP and is adhered to the back side of the rearview mirror 110, namely the lower side in FIG. 2A, by the sealant layer 120. The electroluminescent quantum dot element 100 may provide a light beam L to the light-emitting side (namely the upper side in FIG. 2A), allowing the warning light-transmitting pattern to be observed by the driver. It is worth mentioning that the electroluminescent quantum dot element 100 is a light-emitting element that uses a thin film with quantum dots (QD) as the light-emitting layer and utilizes the principle of electroluminescence to excite the quantum dots to emit light. The electroluminescent quantum dot element 100 has a multi-layer thin-film stacked structure and features low thickness, uniform surface light emission, energy saving, high brightness, high conversion efficiency, and low temperature. These characteristics facilitate easy disposition of the electroluminescent quantum dot element 100 on the rearview mirror 110. From another perspective, compared to traditional light-emitting diodes (LEDs), the electroluminescent quantum dot element 100 may be closer to the groove OP, which significantly increases the viewing angle, making it easier for the driver to observe. For example, in some embodiments, the maximum value of the field of view (FOV) of the electroluminescent quantum dot element 100 may be substantially 140 degrees. A first thickness t1 of the electroluminescent quantum dot element 100 may be less than or equal to 1.4 millimeters.

In some embodiments, opposite sides of the sealant layer 120 in the thickness direction may respectively contact the rearview mirror 110 and the electroluminescent quantum dot element 100. In other words, no light-condensing element, fixing element, light-homogenizing element, optical path adjustment element, or any optical element with diopters or microstructures is disposed between the electroluminescent quantum dot element 100 and the rearview mirror 110. On the basis of omitting secondary optical designs, the volume and structural complexity of the warning light of the blind spot detection device 1 may be significantly reduced, and the versatility of the blind spot detection device 1 is also increased. Additionally, unless otherwise specified below, the thickness of each element refers to the thickness in the stacking direction of the electroluminescent quantum dot element 100, the rearview mirror 110, and the sealant layer 120 in FIG. 2A.

It is worth mentioning that the installation of the electroluminescent quantum dot element 100 requires sealing and closure with the sealant layer 120. The sealant layer 120 has an appropriate thickness to provide vibration buffering, waterproofing, protection, and bonding effects. In other words, on the projection surface of the rearview mirror 110, the sealant layer 120 may be disposed to surround the electroluminescent quantum dot element 100. On the other hand, since the electroluminescent quantum dot element 100 and the rearview mirror 110 are not completely adhered, an increased distance between the electroluminescent quantum dot element 100 and the rearview mirror 110 causes a decrease in the viewing angle of the electroluminescent quantum dot element 100. Additionally, at low angles, the edge of the electroluminescent quantum dot element 100 shows an exposed region with no light emission. Therefore, the width of the electroluminescent quantum dot element 100 needs to be adjusted correspondingly, and a second thickness t2 of the sealant layer 120 needs to be minimized as much as possible to achieve the best display effect. In some embodiments, the second thickness t2 of the sealant layer 120 may be greater than or equal to 0.5 millimeters (mm) and less than or equal to 1 millimeter (mm) to facilitate achieving the aforementioned effects. In some embodiments, a width D of the electroluminescent quantum dot element 100, a width d′ of the surrounding space of the sealant layer 120, and a width d of the groove OP may satisfy the following condition: D>d′>d. In some embodiments, the width D may be substantially 19 mm. However, the disclosure is not limited thereto. In some embodiments, the width d of the groove OP and the width D of the electroluminescent quantum dot element 100 may be adjusted correspondingly to match the required field of view (FOV). Preferably, the width D may be greater than or equal to the width d plus 6.6 mm to achieve the best visible range.

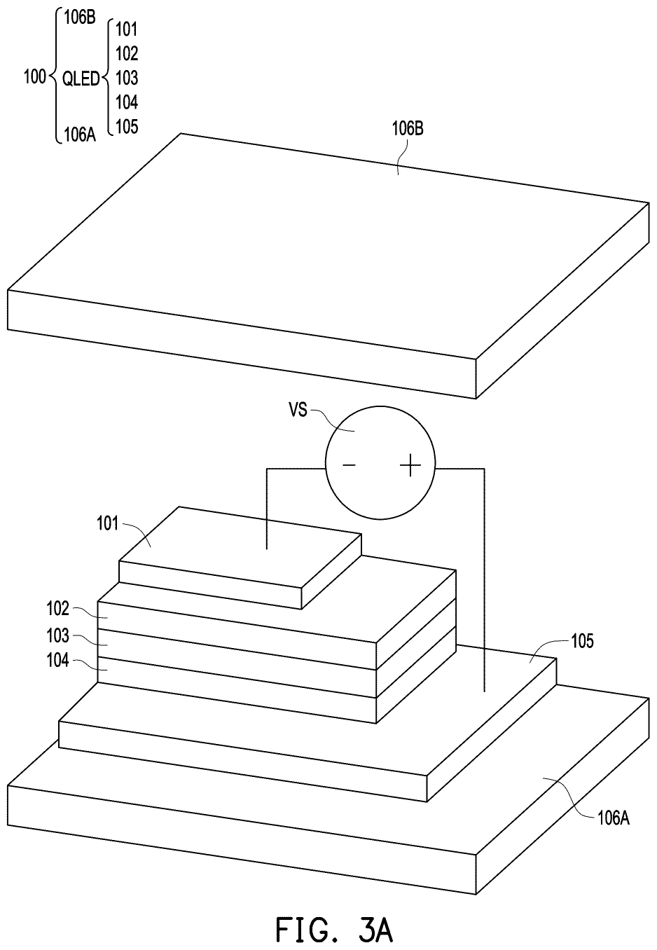

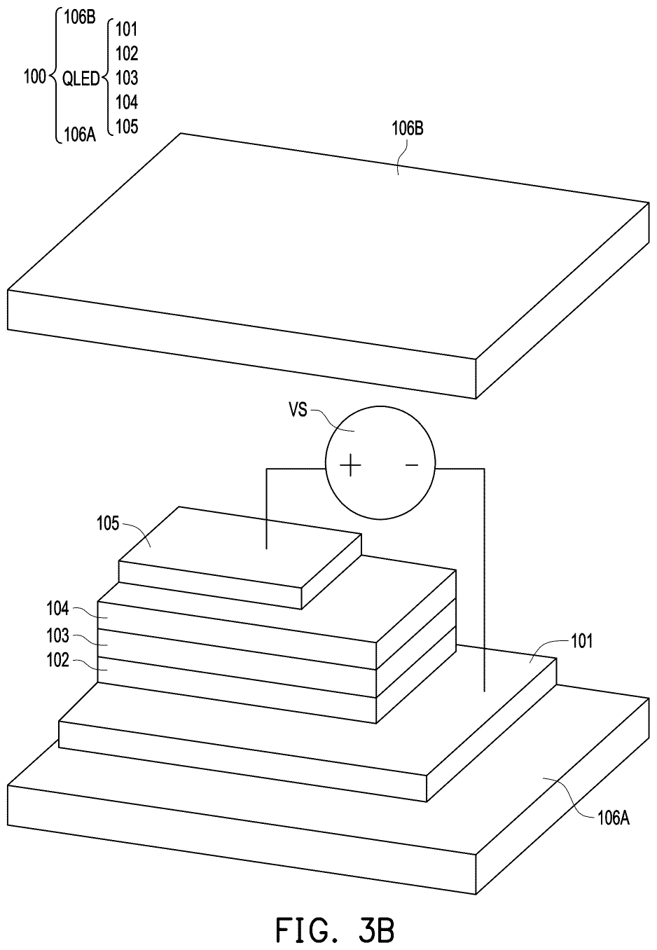

FIGS. 3A and 3B are structural schematic diagrams of the electroluminescent quantum dot element in an embodiment of the blind spot detection device of the disclosure. Referring first to FIG. 3A, the electroluminescent quantum dot element 100 may include a first substrate 106A and a quantum dot light-emitting diode QLED disposed on the first substrate 106A. The electroluminescent quantum dot element 100 may further include a second substrate 106B, and the quantum dot light-emitting diode QLED is disposed between the first substrate 106A and the second substrate 106B. The materials of the first substrate 106A and the second substrate 106B may be glass, quartz, organic polymers, plastic, flexible plastic, or other applicable transparent materials. However, the disclosure is not limited thereto.

On the other hand, the quantum dot light-emitting diode QLED may sequentially include, from bottom to top: a first electrode layer 105 disposed on the first substrate 106A, a hole injection and transport layer 104 disposed on the first electrode layer 105, a quantum dot light-emitting layer 103 disposed on the hole injection and transport layer 104, an electron injection and transport layer 102 disposed on the quantum dot light-emitting layer 103, and a second electrode layer 101 disposed on the electron injection and transport layer 102. In this case, a voltage source VS is respectively connected to the first electrode layer 105 and the second electrode layer 101, which may serve as the anode and the cathode, respectively.

The quantum dot light-emitting layer 103 may be a light-emitting layer having multiple quantum dots. In the quantum dot light-emitting diode QLED, holes from the first electrode layer 105 may be transmitted to the quantum dot light-emitting layer 103 through the hole injection and transport layer 104, while electrons from the second electrode layer 101 may be transmitted to the quantum dot light-emitting layer 103 through the electron injection and transport layer 102. In this case, the transmitted electrons and holes recombine in the quantum dot light-emitting layer 103 to form excitons, thereby emitting light.

Referring again to FIG. 3B, in another embodiment, in the direction from the first substrate 106A to the second substrate 106B, the quantum dot light-emitting diode QLED may also sequentially include the second electrode layer 101, the electron injection and transport layer 102, the quantum dot light-emitting layer 103, the hole injection and transport layer 104, and the first electrode layer 105. The disclosure is not limited thereto.

In an embodiment, the materials of the first electrode layer 105 and the second electrode layer 101 may each include conductive materials, such as indium tin oxide (ITO), aluminum (Al), silver (Ag), chromium (Cr), copper (Cu), nickel (Ni), titanium (Ti), molybdenum (Mo), magnesium (Mg), platinum (Pt), gold (Au), or combinations thereof. In this embodiment, the first electrode layer 105 and the second electrode layer 101 may include the same conductive material or different conductive materials. Taking the quantum dot light-emitting diode QLED of FIG. 3A as an example, since the light beam emitted by the quantum dot light-emitting diode QLED is emitted, for example, toward the lower side, the light beam needs to pass through the first substrate 106A. The first electrode layer 105 is a transparent electrode such as indium tin oxide (ITO) or an extremely thin metal electrode. The disclosure is not limited thereto.

The hole injection and transport layer 104 includes a hole injection layer and a hole transport layer. The material of the hole injection layer may include inorganic materials and organic materials. The inorganic material may include, but is not limited to, suitable materials such as NiO, WO3, and MoO3. The organic material may include, but is not limited to, PEDOT: PSS (Poly (3,4-ethylenedioxythiophene): Poly(styrenesulfonate)) or other suitable materials. Additionally, the material of the hole transport layer may include inorganic materials and organic materials. The inorganic material may include, but is not limited to, NiO. The organic material may include, but is not limited to, suitable materials such as TFB (Poly(9,9-dioctylfluorene-alt-N-(4-sec-butylphenyl)-diphenylamine)) and pTPD (Poly(N,N′-bis-4-butylphenyl-N,N′-bisphenyl)benzidine).

On the other hand, the electron injection and transport layer 102 includes an electron injection layer and an electron transport layer. The material of the electron transport layer may include, but is not limited to, suitable inorganic materials such as ZnO and ZnMgO. On the other hand, the material of the electron injection layer may include, but is not limited to, suitable inorganic materials such as ZnO and LiF. In some embodiments, the electron injection and transport layer 102 may be a single ZnO layer to achieve the functions of electron transport and electron injection.

It should be noted that, in order to improve performance and the viewing angle, the region where the electrons and holes combine may be as close as possible to the hole injection and transport layer 104. Therefore, the electron concentration and mobility in the quantum dot light-emitting layer 103 may be increased, which may increase a field of view FOV as shown in FIG. 2B.

On the other hand, in the present embodiment, the quantum dot light-emitting layer 103 may be formed by depositing quantum dot material into a thin film. However, the disclosure is not limited thereto. In other embodiments, the quantum dot light-emitting layer 103 may include multiple quantum dots uniformly distributed in a matrix material. Quantum dots are extremely small semiconductor nanostructures that are invisible to the naked eye. When quantum dots are excited by external energy (e.g., light or electricity), they emit light with a wavelength in the visible range and a pure color. The color of the light is determined by the composition and particle size of the quantum dots. In other words, a single type of quantum dot may emit light of a single color. For example, the quantum dot light-emitting layer 103 may include red quantum dots, green quantum dots, or blue quantum dots. However, the disclosure is not limited thereto. In some embodiments, when different quantum dot layers respectively include quantum dots of different colors, light of different colors may be mixed to form white light.

In some embodiments, the quantum dots include a core, a core-shell, a core-alloy layer-shell, an alloy-shell, a core (alloy)-multi-layer shell, or combinations thereof. The particle size or dimension of the quantum dots may be adjusted according to requirements (e.g., to emit visible light of different colors). The disclosure is not limited thereto. In some embodiments, the matrix material may include resin materials, such as acrylic resin, epoxy resin, silicone, or combinations thereof.

In an embodiment, the “core” may, for example, include at least one selected from the group consisting of CdS, CdSe, CdTe, ZnS, ZnSe, ZnTe, HgS, HgSe, HgTe, GaN, GaP, GaAs, InP, InAs, InSb, AlN, AIP, AlAs, AlSb, SiC, Fe, Pt, Ni, Co, Al, Ag, Au, Cu, FePt, Si, Ge, PbS, PbSe, PbTe, and alloys thereof. In an embodiment, the “shell” may, for example, include at least one selected from the group consisting of ZnS, ZnSe, ZnTe, CdS, CdSe, CdTe, HgS, HgSe, HgTe, AlN, AIP, AlAs, AlSb, GaN, GaP, GaAs, GaSb, GaSe, InN, InP, InAs, InSb, TIN, TIP, TIAs, TISb, PbS, PbSe, PbTe, and alloys thereof. The core or the shell may be selected according to different requirements. The disclosure is not limited thereto.

It is worth mentioning that the thickness of the quantum dot light-emitting diode QLED may be regarded as the sum of the thicknesses of the first electrode layer 105, the electron injection and transport layer 102, the quantum dot light-emitting layer 103, the hole injection and transport layer 104, and the second electrode layer 101. In some embodiments, the thickness of the quantum dot light-emitting diode QLED may be greater than or equal to 100 nanometers and less than or equal to 300 nanometers. By controlling the position where excitons combine and the overall length of the resonant cavity (i.e., the thickness of the quantum dot light-emitting diode QLED), light emission may be selectively enhanced. For example, to emit red light, the resonant cavity may respond to red light, thereby further increasing the light emission amount of the quantum dot light-emitting diode QLED. On the other hand, the first substrate 106A and the second substrate 106B may have relatively thin thicknesses. For example, in some embodiments, the thicknesses of the first substrate 106A and the second substrate 106B may each be greater than or equal to 0.4 millimeters and less than or equal to 0.7 millimeters (mm). In other words, the aforementioned first thickness t1 of the electroluminescent quantum dot element 100 may be approximately equal to the sum of the thicknesses of the first substrate 106A and the second substrate 106B. Therefore, selecting thinner first substrate 106A and second substrate 106B may reduce the thickness of the electroluminescent quantum dot element 100, thereby allowing the blind spot detection device 1 to have a smaller volume and weight and to be easier to install. This increases the versatility of the blind spot detection device 1. On the other hand, in some embodiments, when the thickness of the first substrate 106A is 0.7 mm, the second thickness t2 is 0.5 mm, and the condition of width D being greater than or equal to width d plus 6.6 mm is satisfied, the field of view FOV of the blind spot detection device 1 may be larger, which is substantially 140 degrees. This achieves an optimal visible range, making it more convenient for the driver to observe.

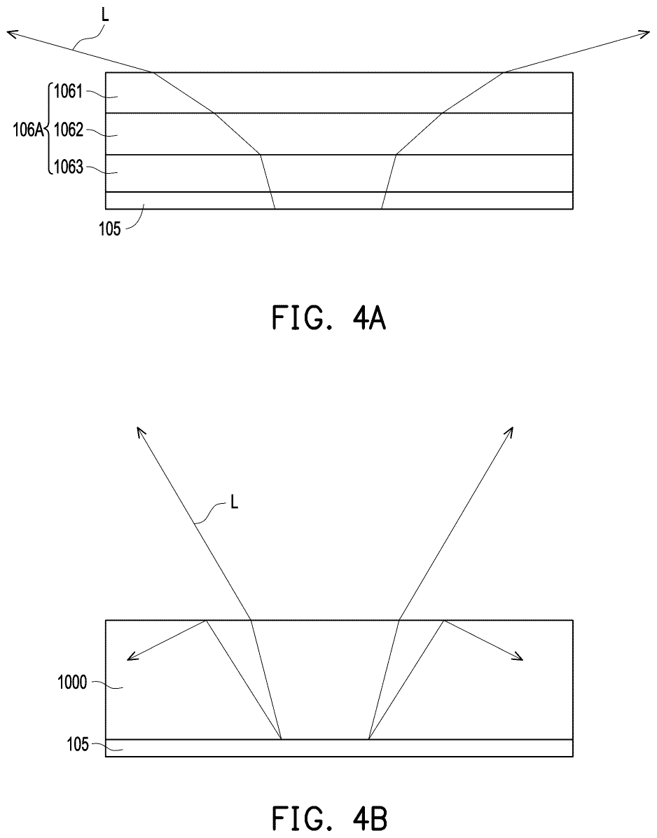

FIG. 4A is a schematic diagram of the light-emitting effect of a substrate with a graded refractive index in an embodiment of the disclosure. FIG. 4B is a schematic diagram of the light-emitting effect of a substrate with a fixed refractive index in a comparative example. Referring to FIGS. 4A and 4B, in some embodiments, one of the first substrate 106A and the second substrate 106B may have a graded refractive index. For example, in FIG. 4A, the first substrate 106A may include a first dielectric layer 1061 having a first refractive index n1, a second dielectric layer 1062 having a second refractive index n2, and a third dielectric layer 1063 having a third refractive index n3. On the side close to the first electrode layer 105, the third dielectric layer 1063 may have a refractive index substantially the same as that of the first electrode layer 105 (e.g., equal to the refractive index of ITO, which is 2.0). On the side away from the first electrode layer 105, the first dielectric layer 1061 may have a lower refractive index (e.g., a refractive index of 1.4). By adjusting the refractive indices of the first electrode layer 105 and the first dielectric layer 1061, the second dielectric layer 1062, and the third dielectric layer 1063 in the first substrate 106A, the occurrence of total reflection when the light beam passes through the first electrode layer 105 and the first substrate 106A may be reduced as much as possible. Therefore, the field of view FOV of the light beam L may be further increased. In contrast, in FIG. 4B, a substrate 1000 is made of, for example, a single light-transmitting material. In this case, only light beams L with smaller divergence angles may exit the substrate 1000. This easily results in a lower viewing angle, and the light output brightness decays severely as the refraction angle increases, affecting the viewing experience of the user.

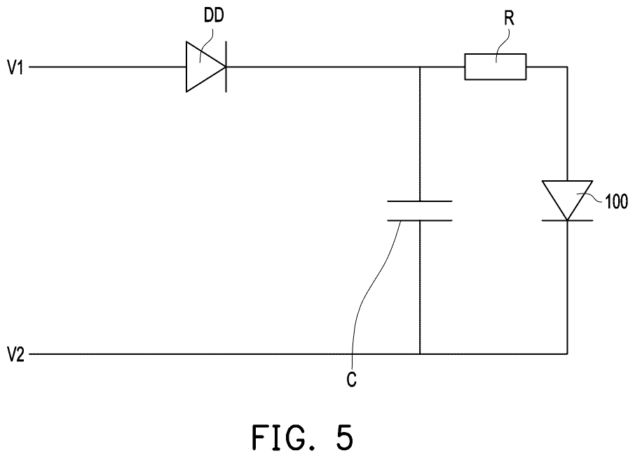

FIG. 5 is a circuit diagram of the blind spot detection device in an embodiment of the disclosure. Referring to FIG. 5, in some embodiments, the blind spot detection device 1 may further include other electronic components. For example, the blind spot detection device 1 may include a current-limiting resistor R connected in series with the electroluminescent quantum dot element 100; a capacitive element C connected in parallel with the electroluminescent quantum dot element 100 and the current-limiting resistor R; and a diode element DD electrically connected to the electroluminescent quantum dot element 100, the capacitive element C, and the current-limiting resistor R.

Specifically, the light emission brightness of the electroluminescent quantum dot element 100 is mainly controlled by the current. Therefore, a voltage stabilizing circuit as shown in FIG. 5 may be designed. For example, a voltage (e.g., 12V) may be generated between voltage V1 and voltage V2. The capacitive element C regulates voltage stabilization, and the current-limiting resistor R maintains a fixed upper limit for the current. This ensures that the current passing through the electroluminescent quantum dot element 100 remains fixed, achieving uniform and consistent brightness over a long period and reducing the chances of damage to the electroluminescent quantum dot element 100. The diode element DD prevents reverse charging when the capacitive element C discharges. Thus, unexpected voltage or current surges that could damage the electroluminescent quantum dot element 100 may be effectively avoided, thereby increasing the stability of the electroluminescent quantum dot element 100.

TABLE 1

| | 4 LEDs Connected | Electroluminescent |
|---|---|---|
| | in Series | Quantum Dot Element 100 |
| Brightness (nit) | 7000 | 7000 |
| Current (mA) | 38 | 80 |
| Voltage (Volt) | 12 | 2.8 |
| Power (mW) | 456 | 224 |
| Temperature (° C.) | 51.6 | 32.6 |

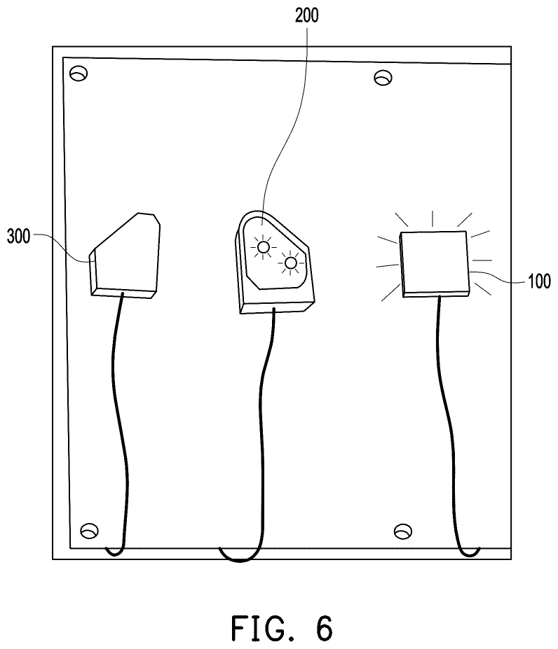

FIG. 6 is a schematic comparison diagram of the blind spot detection device of the disclosure with other light sources. Table 1 is a comparison table of the physical quantities of the electroluminescent quantum dot element 100 and four light-emitting diodes connected in series under the condition of having the same brightness. Referring first to FIG. 5, compared to the structure that uses light-emitting diodes (LEDs) as the illumination indicator light, since LEDs are point light sources, secondary optical designs are required to convert them into surface light sources, as described earlier. The disadvantages include greater thickness, more complex structures, larger light loss, and less uniform light source display. For example, the light source 200, which is an LED point light source, emits light with low uniformity and low brightness. The light source 300, which is an LED point light source combined with a light-homogenizing element, an optical path adjustment element, and various optical modules, is also affected by these components, resulting in a larger volume that is not suitable for applications in different styles of rearview mirrors. In contrast, the electroluminescent quantum dot element 100 of the disclosure has a low thickness, small volume, and is inherently a surface light source. This effectively solves the aforementioned problems. Additionally, its ease of installation indirectly increases the yield rate and product versatility of the blind spot detection device 1.

Furthermore, according to the condition that the electroluminescent quantum dot element 100 and a general LED have the same brightness (e.g., 7000 nits as described in Table 1), the power consumption of the electroluminescent quantum dot element 100 is lower, meaning that the electroluminescent quantum dot element 100 has high light conversion efficiency. This also indicates that the electroluminescent quantum dot element 100 has a lower thermal efficiency, allowing the electroluminescent quantum dot element 100 to maintain a lower temperature during operation. As a result, the chance of thermal damage to the electroluminescent quantum dot element 100 is reduced, indirectly extending the service life of the electroluminescent quantum dot element 100.

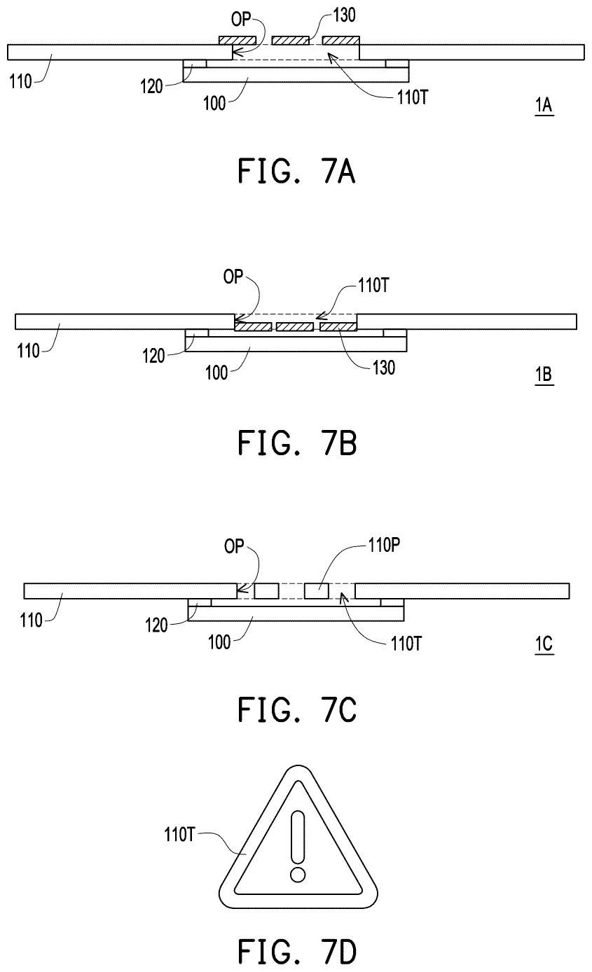

FIGS. 7A to 7C are cross-sectional schematic diagrams of the blind spot detection device in an embodiment of the disclosure. FIG. 7D is a schematic diagram of the warning light pattern presented by the blind spot detection device in an embodiment of the disclosure. Referring first to FIG. 7A, the blind spot detection device 1A is similar to the aforementioned blind spot detection device 1. The main difference is that the blind spot detection device 1A further includes a light-shielding pattern 130, which is disposed on the rearview mirror 110 and overlaps the groove OP of the rearview mirror 110. Further speaking, because the groove OP has a reduced thickness, a partial light-transmitting area 110T may be formed. In the thickness direction of the rearview mirror 110, the groove OP is located between the light-shielding pattern 130 and the electroluminescent quantum dot element 100. The light-shielding pattern 130 may be formed with a material with low visible light transmittance or a metal nameplate. When the light beam emitted by the electroluminescent quantum dot element 100 passes through the partial light-transmitting area 110T, a warning light pattern may be formed (as shown in FIG. 7D). The driver may observe the corresponding warning light pattern through the partial light-transmitting area 110T between the light-shielding pattern 130.

Referring again to FIG. 7B, the blind spot detection device 1B is similar to the blind spot detection device 1A. The main difference is that the light-shielding pattern 130 of the blind spot detection device 1B may be located in the groove OP. This implementation may further reduce the thickness of the components above the rearview mirror 110 and may also achieve the effect of presenting the warning light pattern, as described in the aforementioned embodiments.

Referring again to FIG. 7C, the blind spot detection device 1C is similar to the blind spot detection device 1A. The main difference is that the blind spot detection device 1C may not include the light-shielding pattern 130. However, the groove OP of the rearview mirror 110 further includes a pattern 110P. The pattern 110P may be a region formed with the same material and the same thickness as the rearview mirror 110. For example, the pattern 110P may be formed through etching, thinning, or cutting processes to create the partial light-transmitting area 110T on the rearview mirror 110. From another perspective, the partial light-transmitting area 110T may be the area in the groove OP that does not overlap with the pattern 110P.

In summary, the warning light source of the blind spot detection device in the embodiments of the disclosure is the electroluminescent quantum dot element. Having an extremely low thickness and is a thin-film surface light source, the electroluminescent quantum dot element has advantages such as uniform light emission, energy saving, high brightness, and high light conversion efficiency. When applied to blind spot detection, no secondary optical design (e.g., installing light-homogenizing elements, optical path adjustment elements, or lampshades) is required to convert a point light source into a surface light source. While providing wide-angle light emission to facilitate driver observation, the electroluminescent quantum dot element also reduces the volume of the device. Furthermore, because the thin-film electroluminescent quantum dot element has a uniform and consistent thickness, no special structural processing (e.g., redesigning optical modules, dimensions, or housings) is required for different rearview mirrors. A unified size may be applied to all backlight sources for blind spot detection, and the required pattern or specific size may be displayed through the light-transmitting area of the nameplate. This effectively standardizes the product, significantly reducing costs. Additionally, the left and right rearview mirrors may also be easily shared, increasing the versatility of the product.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A blind spot detection device, comprising:
a rearview mirror, having a groove and a light-transmitting area corresponding to the groove;
an electroluminescent quantum dot element, correspondingly disposed in the groove; and
a sealant layer, disposed between the electroluminescent quantum dot element and the rearview mirror.

2. The blind spot detection device according to claim 1, wherein two opposite sides of the sealant layer respectively contact the rearview mirror and the electroluminescent quantum dot element.

3. The blind spot detection device according to claim 1, wherein a thickness of the sealant layer is less than or equal to 1 millimeter.

4. The blind spot detection device according to claim 1, wherein the electroluminescent quantum dot element comprises:
a first substrate and a quantum dot light-emitting diode disposed on the first substrate, the quantum dot light-emitting diode comprising:
a first electrode layer, disposed on the first substrate;
a hole injection and transport layer, disposed on the first electrode layer;
a quantum dot light-emitting layer, disposed on the hole injection and transport layer;
an electron injection and transport layer, disposed on the quantum dot light-emitting layer; and
a second electrode layer, disposed on the electron injection and transport layer.

5. The blind spot detection device according to claim 4, wherein a thickness of the quantum dot light-emitting diode is greater than or equal to 100 nanometers and less than or equal to 300 nanometers.

6. The blind spot detection device according to claim 4, wherein the electroluminescent quantum dot element comprises:
a second substrate, and the quantum dot light-emitting diode is disposed between the first substrate and the second substrate.

7. The blind spot detection device according to claim 6, wherein one of the first substrate and the second substrate has a graded refractive index.

8. The blind spot detection device according to claim 1, wherein a thickness of the electroluminescent quantum dot element is less than or equal to 1.4 millimeters.

9. The blind spot detection device according to claim 1, wherein a width of the electroluminescent quantum dot element is greater than a width of the groove.

10. The blind spot detection device according to claim 1, further comprising:
a current-limiting resistor, connected in series with the electroluminescent quantum dot element;
a capacitive element, connected in parallel with the electroluminescent quantum dot element and the current-limiting resistor; and
a diode element, electrically connected to the electroluminescent quantum dot element, the capacitive element, and the current-limiting resistor.

11. The blind spot detection device according to claim 1, further comprising:
a light-shielding pattern, overlapping the groove or disposed in the groove, wherein a warning light pattern is formed after a light beam emitted by the electroluminescent quantum dot element passes through the groove.

12. The blind spot detection device according to claim 1, wherein the rearview mirror further comprises a pattern, disposed in the groove, and a warning light pattern is formed after a light beam emitted by the electroluminescent quantum dot element passes through the groove.
